(19) United States
(12) Patent Application Publication
(10) Pub. No.: US 2004/0004499 A1
(43) Pub. Date: Jan. 8, 2004

(54) Semiconductor integrated circuit

(76) Inventor: Masashi Yonemaru, Chiba-shi (JP)

Correspondence Address: HARNESS, DICKEY & PIERCE, P.L.C., P.O. BOX 8910, RESTON, VA, 20195, US

(21) Appl. No.: 10/443,848

(22) Filed: May 23, 2003

(30) Foreign Application Priority Data
May 24, 2002 (JP) 2002-151620

(51) Int. Cl. H03K 19/094

(52) U.S. Cl. 326/113

(57) ABSTRACT

A semiconductor integrated circuit includes a signal output circuit including a first switching device and a second switching device; and a third switching device. The first switching device is supplied with a first voltage via the third switching device. The second switching device is supplied with a second voltage. The signal output circuit receives a first binary signal, and outputs at least one of two values of a second binary signal based on the first binary signal, the first voltage and the second voltage. The third switching device receives a control signal for controlling the third switching device to be in an ON state or in an OFF state; and when the third switching device is in the OFF state, the third switching device turns OFF the supply of the first voltage to the first switching device.

### BACKGROUND OF THE INVENTION

1. Field of the Invention

The present invention relates to a semiconductor integrated circuit for reducing power consumption in an operating state by operating at a low supply voltage and also reducing power consumption in a standby state, i.e., in a non-operating state.

2. Description of the Related Art

As demands for reducing the size and power consumption of integrated circuits are becoming stronger, the threshold voltage of transistors included in integrated circuits tends to be lowered. By use of transistors having a low threshold voltage, semiconductor integrated circuits operable at a high speed and at a low supply voltage can be realized.

However, such a reduction in the threshold voltage of the transistors included in semiconductor integrated circuits results in an increase in the magnitude of the off-leak current of the transistors. Such an increase in the magnitude of the off-leak current is a serious problem especially for semiconductor integrated circuits mounted on mobile terminal devices or the like having a standby mode.

Accordingly, it has been proposed to use a system of using transistors having a high threshold voltage in addition to transistors having a low threshold voltage. With the transistors having a high threshold voltage being used, the magnitude of the leak current, which is generated when a semiconductor integrated circuit including only transistors having a low threshold voltage is used, can be reduced.

FIG. 19 shows a specific configuration of a transistor circuit including transistors having a high threshold voltage in addition to transistors having a low threshold voltage in order to reduce the magnitude of the leak current in a standby state. This specific configuration is shown in Japanese Laid-Open Publication No. 2000-151386.

FIG. 19 shows a path logic circuit for realizing the logical operation of Y=A·B·C. Between an output terminal for outputting Y(=A·B·C) and the GND (ground), a transistor M70 having a high threshold voltage is provided. A source electrode of the transistor M70 is connected to the GND, and a drain electrode of the transistor M70 is connected to the output terminal. A gate electrode of the transistor M70 receives signal /A, which is the inverse of signal A. In this specification, symbol “/” represents the bar; for example, “/X” represents “\overline{X}”.

Between the output terminal and the GND, a transistor M74 having a high threshold voltage, a transistor M72 having a high threshold voltage, and a transistor M71 having a low threshold voltage are connected in series from the side of the GND in this order. A source electrode of the transistor M74 is connected to the GND, and a drain electrode of the transistor M71 is connected to the output terminal. A gate electrode of the transistor M71 receives signal A. A gate electrode of the transistor M72 receives signal /B, which is the inverse of signal B. A gate electrode of the transistor M74 receives signal /C, which is the inverse of signal C.

A transistor M73 having a low threshold voltage is provided in parallel with the transistor M72. A source electrode of the transistor M73 is connected between a drain electrode of the transistor M74 and a source electrode of the transistor M72. The drain electrode of the transistor M73 is connected between a drain electrode of the transistor M72 and a source electrode of the transistor M71. A gate electrode of the transistor M73 receives signal B. The drain electrode of the transistor M74, the source electrode of the transistor M72, and the source electrode of the transistor M74 are connected to the supply voltage Vdd via a transistor M75 having a high threshold voltage, and are connected to the supply voltage Vdd via a transistor M76 having a high threshold voltage. A gate electrode of the transistor M75 receives signal C. The transistor M76 is a pull-up transistor for high-level recovery. A gate electrode of the transistor M76 receives signal C via a buffer 76.

In the path logic circuit shown in FIG. 19, the transistors M70, M72 and M74, the transistor M75 connected to the supply voltage Vdd, and the pull-up transistor M76 have a high threshold voltage. The transistors M71 and M73 which are devices for another network have a low threshold voltage. In this path logic circuit, the transistors M71 and M73 having a low threshold voltage realize a high speed operation. In addition, the magnitude of the leak current is reduced by providing at least one transistor having a high threshold voltage in a path from the supply voltage Vdd or from the ground GND to the output terminal (i.e., a path including the transistor M70 for outputting “L” (=GND) to the output terminal, a path including the transistors M71, M72 and M74, a path including the transistors M71, M73 and M74, or a path including the transistors M75, M73 and M71 for outputting “H” (=Vdd) to the output terminal).

FIG. 20 shows a configuration of another logic circuit, which is connected to a voltage supply circuit. The logic circuit shown in FIG. 20 includes transistors having a high threshold voltage in addition to transistors having a low threshold voltage, in order to reduce the magnitude of the leak current in a standby state. This configuration is disclosed in Japanese Laid-Open Publication No. 6-29834.

A logic circuit 28 shown in FIG. 20 including transistors having a low threshold voltage is supplied with a pseudo voltage V-Vdd by a pseudo power line QL1. The pseudo power line QL1 is connected to a power line PL1 providing the supply voltage Vdd via a transistor M77 having a high threshold voltage. The logic circuit 28 is also supplied with a pseudo voltage V-GND by a pseudo power line QL2. The pseudo power line QL2 is connected to the GND via a transistor M78 having a high threshold voltage.

A gate electrode of the transistor M77 connected to the power line PL1 receives a control signal SL. A gate electrode of the transistor M78 connected to the GND receives a control signal SLB, which is the inverse of control signal SL. While the logic circuit 28 is in an operating state, the transistors M77 and M78 are controlled to be ON by control signals SL and SLB respectively, and a prescribed voltage is applied to the logic circuit 28 by the pseudo power lines QL1 and QL2. While the logic circuit 28 is in a standby mode, the transistors M77 and M78 are controlled to be OFF by control signals SL and SLB respectively, and the pseudo power lines QL1 and QL2 are disconnected from the power line PL1 and the GND. Thus, the magnitude of the leak current in a standby state is reduced.

However, the logic circuit 28 is operated by the power supplied via the transistors M77 and M78. Transistors have a certain level of ON resistance. Thus, where the transistors are used as switching devices, the voltage of the transistors is reduced by the consumed current of the logic circuit 28 and the ON resistance. As a result, the voltages V-Vdd and V-GND of the pseudo power lines QL1 and QL2, respectively, are changed. When the voltages of the pseudo power lines QL1 and QL2 are changed, the operating characteristics of the logic circuit 28 including only the transistors having a low threshold voltage are deteriorated.

In order to suppress such a change in the voltages, the circuit configuration shown in FIG. 20 includes a capacitor C10 inserted between the power line PL1 and the pseudo power line QL1 and a capacitance C11 inserted between the GND and the pseudo power line QL2.

FIG. 21 shows a configuration of still another logic circuit including transistors having a high threshold voltage in addition to transistors having a low threshold voltage in order to reduce the magnitude of the leak current in a standby state. This configuration is disclosed in Japanese Laid-Open Publication No. 10-224206.

In a logic circuit 29 shown in FIG. 21, transistors M79, M80, M81 and the like having a high threshold voltage form a path logic circuit. A buffer circuit 30 is connected to an input terminal of the path logic circuit, and a buffer circuit 31 is connected to an output terminal of the path logic circuit.

FIG. 22 shows a configuration proposed for the buffer circuits 30 and 31.

In the configuration shown in FIG. 22, a signal is input to a source electrode of a transistor M82 connected to an input terminal of the buffer circuit 30, 31. The signal is output to an inverter 32 connected to a drain electrode of the transistor M82. An output from the inverter 32 is further input to an inverter 33, and an output from the inverter 33 is input to a source electrode of the transistor M83. A signal which is output from a drain electrode of the transistor M83 is the output of the buffer circuit 30, 31. An inverter 34 inverts the output signal from the inverter 32 and feeds the inverted signal back to the input of the inverter 32, so as to maintain the level of the output signal of the inverter 32. A gate electrode of the transistor M82 and a gate electrode of the transistor M83 each receive a CRTL signal to perform ON/OFF control of the transistors M82 and M83, respectively.

The transistors included in the buffer circuit 30, 31 have a threshold voltage which is higher than the usual threshold voltage (i.e., the threshold voltage of the transistors M79, M80 and the like included in the path logic circuit).

An operation of the buffer circuit 30, 31 will be described.

A signal which is input to the transistor M82 is input to the inverter 32. The inverter 32 receives the signal from an input end thereof, and inverts and outputs the received signal to an output end thereof. The signal output from the inverter 32 is again inverted by the inverter 34 and fed back to the input end of the inverter 32. Thus, the level of this signal is maintained. The signal output from the inverter 32 is also input to the inverter 33, and is inverted to be output. The transistor M83 outputs the signal from the inverter 33 as an output from the buffer circuit 30, 31.

The ON/OFF state of the transistors M82 and M83 provided in the buffer circuit 30, 31 as described above are controlled by a CTRL signal. While the buffer circuit 30, 31 is in an operating state, the transistors M82 and M83 are controlled to be ON by the CTRL signal, and thus the buffer circuit 30, 31 acts as a buffer. Thus, a signal input to the input terminal of the buffer circuit 30, 31 is output from the output terminal thereof. While the buffer circuit 30, 31 is in a standby state (i.e., in a non-operating state), the transistors M82 and M83 are controlled to be OFF by the CTRL signal. Thus, the inverters 32 and 33 are disconnected from the path logic circuit. Owing to the structure in which the inverters 32 and 33 are disconnected from a signal transmission circuit for transmitting a signal to the path logic circuit, the magnitude of the leak current can be reduced.

The logic circuits described in the above-mentioned three publications have the following problems.

In the path logic circuit shown in FIG. 19, it is necessary to analyze the leak path of each path of the network paths included in the logic circuit to locate a transistor having a high threshold voltage in accordance with the analysis result. When the semiconductor integrated circuit is of a large scale, such necessary operations are difficult. The load of these operations can be alleviated by use of CAD or the like, but this requires software or a system for a complicated leak path analysis to be newly developed.

When the logic circuit 28 shown in FIG. 20 is operated at a high speed, the magnitude of the instantaneous current consumed increases. This requires the capacitances of the capacitors C10 and C11 inserted for suppressing voltage changes to be increased. As such, in order to realize an integrated circuit providing a high speed operation using the logic circuit 28, it is necessary to reduce the resistances of the transistors M77 and M78 acting as switching devices or to increase the capacitances of the capacitors C10 and C11. In either case, the size of the transistors M77 and M78 or the capacitors C10 and C11 need to be made larger. This does not comply with the purpose of reducing the size of the integrated circuit.

In the path logic circuit shown in FIG. 21, as described in Japanese Laid-Open Publication No. 10-224206, the transistors M82 and M83 are used in order to disconnect the inverters 32 and 33 from the signal transmission circuit for transmitting a signal to the path logic circuit. This reduces the output potential of the “H” signal of the path logic circuit from the potential of the supply voltage Vdd to Vdd−(Vth+Vα) by the threshold voltage (Vth) of the transistors M82 and M83 and the increase in the threshold voltage (Vα) due to the substrate effect. In the example shown in FIG. 22, the transistors M82 and M83 are used in order to reduce the magnitude of the leak current. When the threshold voltage of the transistors M82 and M83 is increased to VthH, the output level of the “H” signal is still lowered to Vdd−(VthH+Vα). This reduces the noise margin.

In the path logic circuit shown in FIG. 21, the transistors M79, M80 and M81 are connected in series. The path logic circuit having such a configuration operates as follows when the level of the input signal IN is changed from “L” (=0) to “H” (=Vdd) as shown in FIG. 23. The output signal (a) from the transistor M79 slowly increases as approaching the level“H”. This is because as the output voltage (a) of the transistor M79 approaches the level “H”, the potential difference between the source electrode and the drain electrode of the transistor M79 is reduced and thus the magnitude of the drain current is reduced. The output signal of the transistor M79 is Vdd−(Vth+Vα), which is lower than the supply voltage Vdd, due to the above-mentioned threshold voltage and the substrate effect.

The output signal (b) of the next-stage transistor M80 which receives the output signal (a) from the transistor M79 increases more slowly than the output signal (a) as approaching the level “H”. This is because as the output voltage (b) of the transistor M80 approaches the level “H”, the potential difference between the source electrode and the drain electrode of the transistor M80 is reduced and thus the magnitude of the drain current is reduced.

Similarly, the output signal (c) of the next-stage transistor M81 which receives the output signal (b) from the transistor M80 increases still more slowly than the output signal (b) as approaching the level “H”.

As described above with reference to FIG. 23, a path logic circuit has a problem in that as the number of transistors connected in series for a network increases, the transmission signal deteriorates and causes an increase in the delay time and an increase in the current consumption.

In order to prevent increase in the delay time and increase in the current consumption, it is desirable to minimize the number of path transistors connected in series in a path logic circuit. In the path logic circuit shown in FIG. 21, the buffer circuits 30 and 31 are respectively connected to the input terminal and the output terminal of the path logic circuit. As shown in FIG. 22, each buffer circuit 30, 31 includes the two transistors M82 and M83.

In this configuration, the transistors M79, M80 and M81 of the path logic circuit are connected in series for a network circuit, and in addition the transistors M82 and M83 included in each buffer circuit 30, 31 are also connected in series. This deteriorates the transmission signal, increases the delay time, and increase the current consumption.

### SUMMARY OF THE INVENTION

A semiconductor integrated circuit according to the present invention includes a signal output circuit including a first switching device and a second switching device; and a third switching device. The first switching device is supplied with a first voltage via the third switching device. The second switching device is supplied with a second voltage. The signal output circuit receives a first binary signal, and outputs at least one of two values of a second binary signal based on the first binary signal, the first voltage and the second voltage. The third switching device receives a control signal for controlling the third switching device to be in an ON state or in an OFF state; and when the third switching device is in the OFF state, the third switching device turns OFF the supply of the first voltage to the first switching device.

In one embodiment of the invention, the first switching device, the second switching device, and the third switching device are transistors. The third switching device has a threshold voltage which is higher than a threshold voltage of the first switching device and a threshold voltage of the second switching device.

In one embodiment of the invention, the signal output circuit further includes a fourth switching device supplied with the second voltage. The fourth switching device receives the control signal and is controlled to be in an ON state when the third switching device is in an OFF state. The fourth switching device is in an ON state, the signal output signal outputs one of two values of the second binary signal and does not output the other value irrespective of the value of the first binary signal.

In one embodiment of the invention, the first switching device, the second switching device, the third switching device, and the fourth switching device form a NAND circuit for receiving the first binary signal and the control signal. The first voltage is a ground voltage. The third switching device is an n-channel transistor, and a source electrode of the third switching device is grounded.

In one embodiment of the invention, the first switching device, the second switching device, the third switching device, and the fourth switching device form a NOR circuit for receiving the first binary signal and the control signal. The first voltage is a supply voltage. The third switching device is a p-channel transistor, and a source electrode of the third switching device is supplied with the supply voltage.

In one embodiment of the invention, the semiconductor integrated circuit further includes a logic operation circuit for performing a logic operation, wherein the first binary signal represents a result of the logic operation performed by the logic operation circuit.

In one embodiment of the invention, the first voltage is one of a supply voltage and a ground voltage, and the second voltage is the other of the supply voltage and the ground voltage.

In one embodiment of the invention, the third switching device is a transistor having a body electrode. The third switching device has a threshold voltage which changes based on the voltage applied to the body electrode.

In one embodiment of the invention, the first switching device and the second switching device are transistors. When the third switching device is in an OFF state, the threshold voltage of the switching device is higher than a threshold voltage of the first switching device and a threshold voltage of the second switching device.

In one embodiment of the invention, the third switching device is a transistor having a gate electrode and a body electrode. The gate electrode and the body electrode are electrically connected to each other.

In one embodiment of the invention, the semiconductor integrated circuit further includes a diode connected between the gate electrode and the body electrode.

In one embodiment of the invention, at least one of the first switching device, the second switching device, and third switching device is a transistor having an SOI structure.

In one embodiment of the invention, the semiconductor integrated circuit further includes a fourth switching device connected between the first switching device and the third switching device. The third switching device and the fourth switching device are transistors. The third switching device and the fourth switching device are connected in series. The third switching device is in an ON state, the fourth switching device is in an ON state; and when the third switching device is in an OFF state, the fourth switching device is in an OFF state.

In one embodiment of the invention, the first switching device, the second switching device, the third switching device, and the fourth switching device are transistors. The first switching device, the second switching device, the third switching device, and the fourth switching device have threshold voltages having an equal absolute value.

In one embodiment of the invention, the first switching device and the second switching device form a complementary switching device.

As described above, a semiconductor integrated circuit according to the present invention includes a switching device for turning OFF the supply of a voltage to a signal output circuit when the logic operation circuit is in a non-operating state. Owing to this structure, the magnitude of the leak current in the non-operating state can be reduced.

According to the present invention, since the semiconductor integrated circuit includes the signal output circuit and the switching device, the magnitude of the leak current in a non-operating state can be easily reduced by simple circuitry regardless of the structure of the network logic circuit. Thus, the magnitude of the leak current in a non-operating state can be reduced without troublesome operations of analyzing the leak path and inserting a transistor having a high threshold voltage for each path, without unnecessarily increasing the chip area, or without increasing the number of transistors and thus without deteriorating the characteristics of the network logic circuit.

According to the present invention, the switching device for turning OFF the supply of a voltage to the signal output circuit in anon-operating state may be, for example, a transistor having a high threshold voltage, a transistor having a body electrode having an adjustable threshold voltage, a transistor having a gate electrode and a body electrode connected to each other, or a combination of a plurality of transistors having a low threshold voltage connected in series. Since such a switching device, which can effectively prevent the leak current is used, transistors having a low threshold voltage can be used for other transistors in the semiconductor integrated circuit. Thus, a semiconductor integrated circuit operating at a high speed while preventing leak current in a non-operating state can be provided.

Thus, the invention described herein makes possible the advantages of providing a semiconductor integrated circuit for reducing the magnitude of the current consumed in a standby state with a simpler structure, without increasing the chip area, and without increasing the number of transistors and thus without deteriorating the characteristics of the path logic circuit.

These and other advantages of the present invention will become apparent to those skilled in the art upon reading and understanding the following detailed description with reference to the accompanying figures.

### BRIEF DESCRIPTION OF THE DRAWINGS

FIG. 1 is a block diagram illustrating a semiconductor integrated circuit according to a first example of the present invention;

FIG. 2 is a block diagram more specifically illustrating the semiconductor integrated circuit according to the first example of the present invention;

FIG. 3 is a circuit diagram of a path logic circuit;

FIG. 4 is a circuit diagram illustrating a leak current path in a path logic circuit shown in FIG. 3 in a standby state;

FIG. 5 is a circuit diagram of a path logic circuit in which one input terminal of a network logic circuit is connected to the ground GND;

FIG. 6 is circuit diagram of a leak current path of the path logic circuit shown in FIG. 5 in a standby state;

FIG. 7 is a circuit diagram of a buffer circuit connected to a transistor having a low threshold voltage;

FIG. 8 is a block diagram of a semiconductor integrated circuit according to a second example of the present invention;

FIG. 9 is a path logic circuit;

FIG. 10 is a circuit diagram of a leak current path of the path logic circuit shown in FIG. 9 in a standby state;

FIG. 11 is a circuit diagram of a leak current path in a standby state when one input terminal of a network logic circuit is connected to the ground GND;

FIG. 12 is a circuit diagram of a buffer circuit connected to a transistor having a low threshold voltage;

FIG. 13 is a block diagram illustrating a semiconductor integrated circuit according to a third example of the present invention;

FIG. 14 is a block diagram illustrating a semiconductor integrated circuit according to a fourth example of the present invention;

FIG. 15A is a circuit diagram of a circuit for solving the problem of increase in the magnitude of the leak current described in the fourth example;

FIG. 15B is a graph illustrating the relationship between the supply voltage with the drain current I_{D} and the leak current Iₗₑₐₖ in the circuit shown in FIG. 15A;

FIG. 16A shows a fully depleted (FD)-type transistor;

FIG. 16B shows a partially depleted (PD)-type transistor;

FIG. 17 is a block diagram of a semiconductor integrated circuit according to a fifth example of the present invention;

FIG. 18A is a circuit diagram of a transistor having a low threshold voltage;

FIG. 18B is a circuit diagram of a configuration of a transistor according to the fifth example;

FIG. 18C is a graph illustrating an off-leak current characteristic of a single transistor having a low threshold voltage;

FIG. 18D is a graph illustrating an off-leak current characteristic of a transistor according to the fifth example;

FIG. 19 is a circuit diagram of a conventional transistor circuit;

FIG. 20 is a circuit diagram of a conventional logic circuit;

FIG. 21 is a circuit diagram of a conventional logic circuit;

FIG. 22 is a circuit diagram of a buffer circuit included in the logic circuit shown in FIG. 21; and

FIG. 23 is a graph illustrating the deterioration in a transmission signal generated in the logic circuit shown in FIG. 21.

### DESCRIPTION OF THE PREFERRED EMBODIMENTS

Hereinafter, the present invention will be described by way of illustrative examples with reference to the accompanying drawings.

### EXAMPLE 1

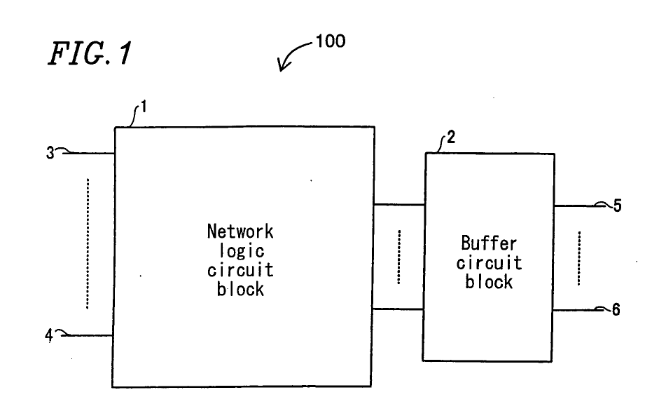

FIG. 1 is a block diagram illustrating a semiconductor integrated circuit 100 according to a first example of the present invention.

The semiconductor integrated circuit 100 includes a network logic circuit block 1 for performing a prescribed logic operation so as to generate a logic circuit signal which represents an operation result, and a buffer circuit block 2 connected to the network logic circuit block 1 for amplifying the logic circuit signal generated by the network logic circuit block 1. The network logic circuit block 1 includes input terminals 3 and 4 for receiving an input signal. The buffer circuit block 2 includes output terminals 5 and 6 for outputting a signal amplified by the buffer circuit block 2.

The network logic circuit block 1 includes MOS transistors having a low threshold voltage for increasing the speed of logic operations. (In the following description, the term “transistor” refers to a MOS transistor, unless otherwise specified.) Transistors usable with the present invention are not limited to MOS transistors. The buffer circuit block 2 includes transistors having a low threshold voltage for increasing the speed of processing signals from the network logic circuit block 1, and also includes a transistor having a high threshold voltage in a prescribed portion thereof for reducing the magnitude of the leak current in a standby state (i.e., non-operating state) of the network logic circuit block 1. Thus, since the buffer circuit block 2 includes a transistor having a high threshold voltage in a prescribed portion thereof, the magnitude of the leak current flowing through the leak path can be reduced.

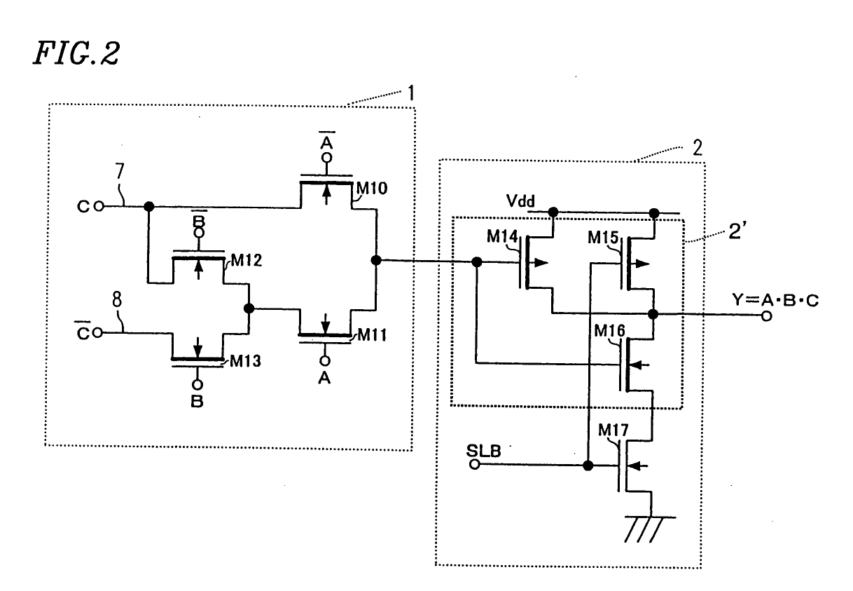

FIG. 2 is a block diagram more specifically illustrating the network logic circuit block 1 and the buffer circuit block 2 in the semiconductor integrated circuit 100 in the first example. In this example, the semiconductor integrated circuit 100 performs a Y=A·B·C operation, for example.

The network logic circuit block 1 includes therein a first input terminal 7 for receiving signal C, and a second input terminal 8 for receiving signal /C, which is the inverse of signal C. The first input terminal 7 is connected to a source electrode of an n-channel transistor M10 and a source electrode of an n-channel transistor M12. The second input terminal 8 is connected to a source electrode of an n-channel transistor M13. A drain electrode of the transistor M12 and a drain electrode of the transistor M13 are connected to a source electrode of an n-channel transistor M11. Outputs from a drain electrode of the transistor M10 and a drain electrode of the transistor M11 are sent to the buffer circuit block 2 as a binary signal from the network logic circuit block 1.

A gate of the transistor M11 receives signal A, and a gate electrode of the transistor M10 receives signal /A, which is the inverse of signal A. A gate electrode of the transistor M13 receives signal B, and a gate electrode of the transistor M12 receives signal /B, which is the inverse of signal B.

The transistors M10, M11, M12 and M13 included in the network logic circuit block 1 each have a low threshold voltage, and therefore can operate at a high speed.

The buffer circuit block 2 includes transistors M14 (p-channel transistor), M15 (p-channel transistor), M16 (n-channel transistor) and M17 (n-channel transistor), which form a NAND circuit. The transistors M14, M15 and M16 form a signal output circuit 2′. A source electrode of the transistor M14 and a source electrode of the transistor M15 are connected to the supply voltage Vdd, and the transistors M14 and M15 are connected in parallel. A source electrode of the transistor M17 is connected to the ground GND, and a drain electrode of the transistor M17 is connected to a source electrode of the transistor M16. Outputs from a drain electrode of the transistor M14, a drain electrode of the transistor M15, and a drain electrode of the transistor M16 are output as a binary signal from the buffer circuit block 2. The signals from the transistors M14 and M15 are “H” (=Vdd), and the signal from the transistor M16 is “L” (=GND).

A gate electrode of the transistor M14 and a gate electrode of the transistor M16, both acting as a first input of the buffer circuit block 2, each receive the binary signal from the network logic circuit block 1. A gate electrode of the transistor M15 and a gate electrode of the transistor M17, both acting as a second input of the buffer circuit block 2, each receive a standby/operation control signal (hereinafter, referred to as a “signal SLB”).

In the buffer circuit block 2, the transistor M17 connected to the ground GND has a high threshold voltage, and the transistors M14, M15 and M16 each have a low threshold voltage.

While the network logic circuit block 1 is in an operating state, the signal SLB is “H”. The transistor M17 having a high threshold voltage, which receives the “H” signal SLB, is controlled to be ON, thereby equalizing the potential of the source electrode of the transistor M16 with the level of the ground GND. The transistor M15, which also receives the “H” signal SLB, is controlled to be OFF. Owing to such a level control of the transistors M15 (OFF) and M17 (ON), the buffer circuit block 2 acts as an inverter circuit for inverting and amplifying a signal from the network logic circuit block 1. Since the signal from the network logic circuit block 1 is received by the transistors M14 and M16 both having a low threshold voltage, the buffer circuit block 2 operates at a high speed.

While the network logic circuit block 1 is in a standby state, the signal SLB is “L”. The transistor M17 having a high threshold voltage, which receives the “L” signal SLB, is controlled to be OFF, and the transistor M15, which also receives the “L” signal SLB, is controlled to be ON. Owing to such a level control of the transistors M15 (ON) and M17 (OFF), the buffer circuit block 2 outputs a fixed “H” signal (=Vdd) irrespective of the level of the signal from the network logic circuit block 1. Since the transistor M17, controlled to be OFF, blocks the transistor M16 from the ground GND and has a small amount of off-leak current because of its high threshold voltage, the magnitude of the leak current in the buffer circuit block 2 is reduced.

The transistors M14, M15 and M16 are set to have a threshold voltage which is sufficiently low to operate at a high speed with the specific supply voltage used. For example, when the supply voltage Vdd=0.5 V, the threshold voltage of each of the transistors M14, M15 and M16 is set to 0.15 V. The transistor M17 is set to have a threshold voltage which is sufficiently high to reduce the magnitude of the leak current, for example, 0.4 V in this case.

A path logic circuit is a circuit which uses transistors as switching devices and combines gates of the transistors receiving an input signal to form a network, thus performing a logic operation. A path logic circuit includes a network logic circuit for performing a logic operation and a buffer circuit for shaping the waveform of, and amplifying, the signal output from the network logic circuit.

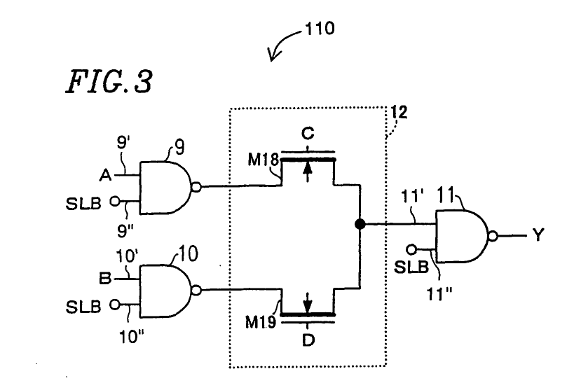

FIG. 3 is a block diagram schematically illustrating such a path logic circuit 110.

The path logic circuit 110 shown in FIG. 3 includes a network logic circuit 12, which includes transistors M18 and M19 both having a low threshold voltage. A source electrode of the transistor M18 is connected a buffer circuit 9, and the transistor M18 is driven by the buffer circuit 9. A source electrode of the transistor M19 is connected a buffer circuit 10, and the transistor M19 is driven by the buffer circuit 10. A drain electrode of the transistor M18 and a drain electrode of the transistor M19 are both connected to an input terminal of a buffer circuit 11. Outputs from the drains of the transistors M18 and M19 are sent to the buffer circuit 11 as outputs from the network logic circuit 12.

The buffer circuits 9, 10 and 11 each include a NAND circuit having two input terminals. One input terminal of the buffer circuit 9 receives signal A, and one input terminal of the buffer circuit 10 receives signal B. One input terminal of the buffer circuit 11 receives a signal from the network logic circuit 12. The other input terminals of the buffer circuits 9, 10 and 11 each receive a signal SLB. An output terminal of the buffer circuit 11 outputs signal Y.

Hereinafter, reduction in the magnitude of the leak current realized by the semiconductor integrated circuit 100 of the first example will be described in more detail, with the path logic circuit 110 as an example.

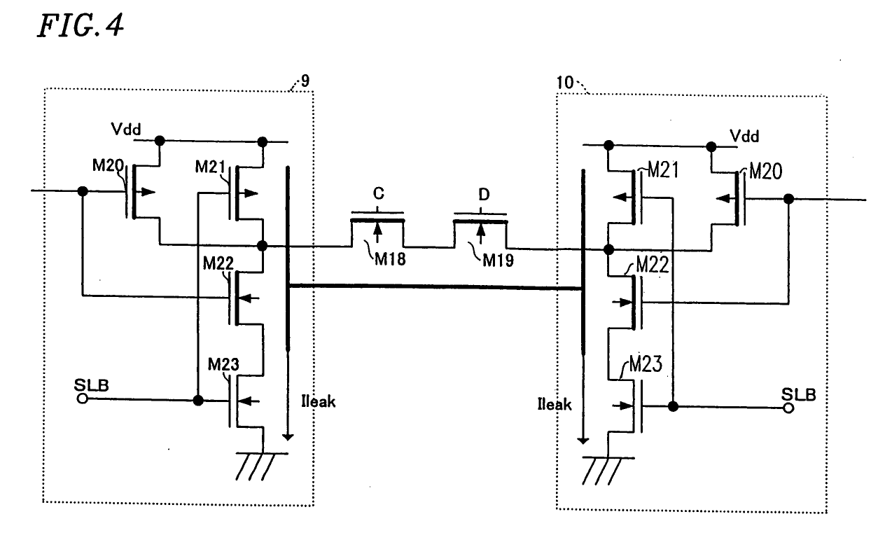

FIG. 4 is a circuit diagram illustrating a leak current path of the path logic circuit 110 (FIG. 3). With reference to FIG. 4, the leak current path when the path logic circuit 110 is in a standby state will be described in more detail. The buffer circuits 9 and 10 each have the same circuit configuration as that of the buffer circuit block 2 shown in FIG. 2, except that transistors M20 through M23 respectively correspond to the transistors M14 through M17.

In the example of FIG. 4, a leak current path is formed in a standby state between the supply voltage Vdd and the ground GND. The leak current path includes the transistors M18 and M19 included in a network logic circuit, and the transistors M20, M21, M22 and M23 in each of the buffer circuits 9 and 10. A leak current Iₗₑₐₖ flowing through the leak current path from the supply voltage Vdd is generated. While the path logic circuit 110 is in a standby state, the signal SLB is “L”, and the transistor M23 having a high threshold voltage, which receives the “L” signal SLB, is controlled to be OFF. Therefore, the leak current path is isolated from the ground GND by the transistor M23, and as a result, the magnitude of the leak current Iₗₑₐₖ flowing through the leak current path can be reduced.

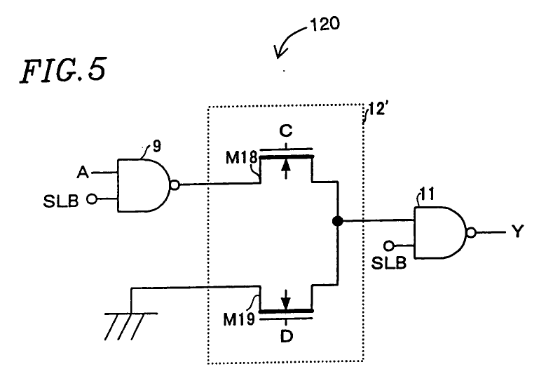

FIG. 5 is a block diagram of a path logic circuit 120 in which one input terminal of the network logic circuit is connected to the ground GND in a fixed manner. FIG. 6 is a circuit diagram illustrating a leak current path of the path logic circuit 120 (FIG. 5). With reference to FIG. 6, the leak current path when the path logic circuit 120 is in a standby state will be described in more detail. The buffer circuit 9 has the same circuit configuration as that of the buffer circuit block 2 shown in FIG. 2, except that transistors M20 through M23 respectively correspond to the transistors M14 through M17.

In the example of FIG. 6, while the path logic circuit 120 is in a standby state, the signal SLB is “L”, and the transistor M23 having a high threshold voltage, which receives the “L” signal SLB, is controlled to be OFF. Therefore, the leak current path is isolated from the ground GND by the transistor M23, and as a result, the magnitude of the leak current Iₗₑₐₖ flowing through the leak current path which is from the supply voltage Vdd to the ground GND via the transistor M23 can be reduced.

However, one of the two transistors M19 in a network logic circuit 12′ is connected to the ground GND. Therefore, while the path logic circuit 120 is in a standby state (non-operating state), a leak current Iₗₑₐₖ is generated flowing from the transistor M21 controlled to be ON to the ground GND via the transistors M18 and M19 in the network logic circuit 12′. In order to block the leak path by the buffer circuit 9 stably and certainly so as to reduce the magnitude of the leak current Iₗₑₐₖ, all the input terminals of the network logic circuit need to be connected to a NAND circuit as shown in FIG. 2 including a transistor which has a high threshold voltage and is connected to the ground GND.

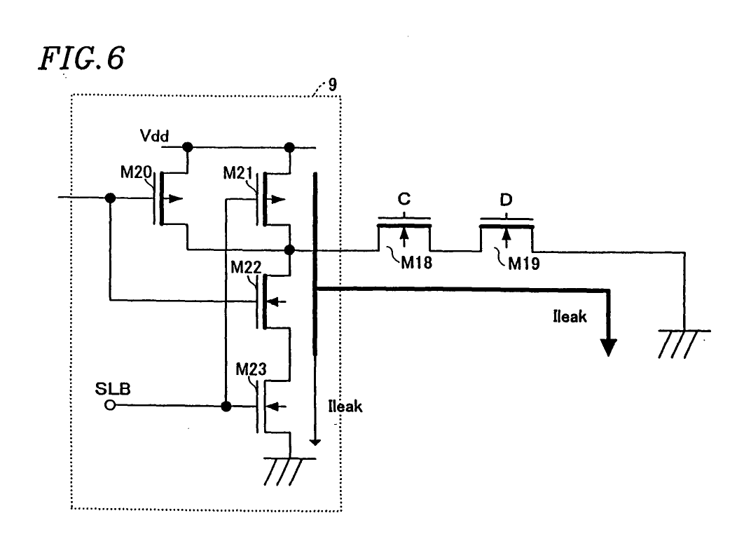

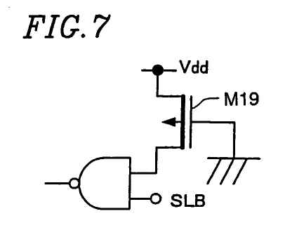

FIG. 7 shows a circuit configuration proposed to eliminate the leak path described above with reference to FIGS. 5 and 6. The circuit configuration shown in FIG. 7 level-clips the source electrode of the transistor M19 to the ground GND via a buffer circuit. In this case also, the buffer circuit needs to be a NAND circuit as shown in FIG. 2.

As described above, the semiconductor integrated circuit 100 according to the first example includes a NAND-type buffer circuit block 2. One of the two input terminals of the NAND-type buffer circuit block 2 receives a standby/operation control signal SLB, and the signal SLB is input to the transistor M17 having a source electrode connected to the ground GND. The transistor M17 has a high threshold voltage. The buffer circuit block 2, owing to the above-described structure, can easily reduce the magnitude of the leak current irrespective of the structure of the network logic circuit block 1. While the network logic circuit block 1 is in a standby state, the transistor having a high threshold voltage is controlled to be ON by the signal SLB whereas the transistors switched by the input signal have a low threshold voltage. Therefore, the semiconductor integrated circuit 100 can realize high speed processing.

### EXAMPLE 2

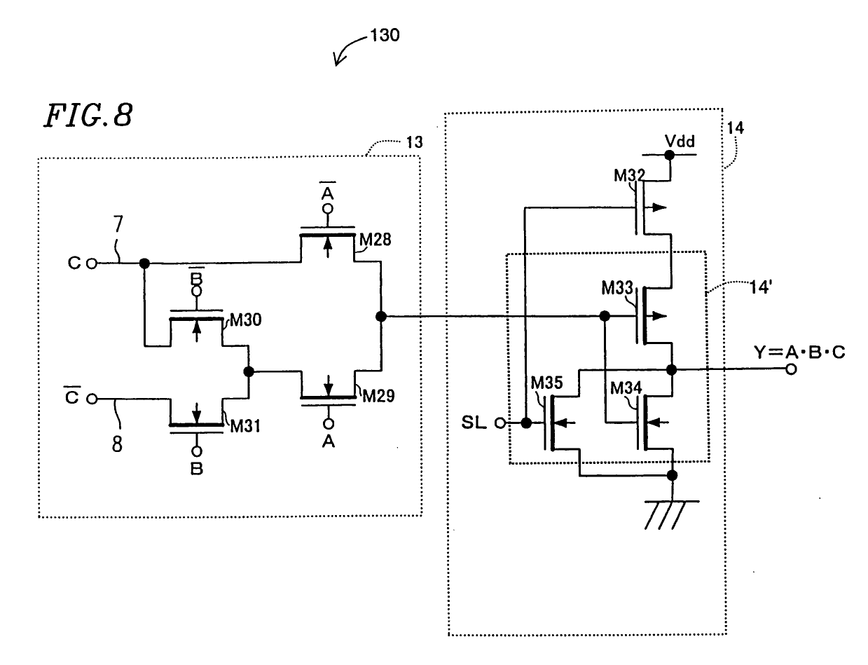

FIG. 8 is a block diagram illustrating a semiconductor integrated circuit 130 according to a second example of the present invention. In this example, the semiconductor integrated circuit 100 performs a Y=A·B·C operation, for example.

The semiconductor integrated circuit 130 includes a network logic circuit block 13 for performing a prescribed logic operation so as to generate an operation circuit signal, and a buffer circuit block 14 connected to the network logic circuit block 13 for amplifying the operation circuit signal generated by the network logic circuit block 13.

The network logic circuit block 1 includes therein a first input terminal 7 for receiving signal C, and a second input terminal 8 for receiving signal /C, which is the inverse of signal C. The first input terminal 7 is connected to a source electrode of an n-channel transistor M28 and a source electrode of an n-channel transistor M30. The second input terminal 8 is connected to a source electrode of an n-channel transistor M31. A drain electrode of the transistor M30 and a drain electrode of the transistor M31 are connected to a source electrode of an n-channel transistor M29. Outputs from a drain electrode of the transistor M28 and a drain electrode of the transistor M29 are sent to the buffer circuit block 2 as a binary signal from the network logic circuit block 13.

A gate of the transistor M29 receives signal A, and a gate electrode of the transistor M28 receives signal /A, which is the inverse of signal A. A gate electrode of the transistor M31 receives signal B, and a gate electrode of the transistor M30 receives signal /B, which is the inverse of signal B.

The transistors M28, M29, M30 and M31 included in the network logic circuit block 13 each have a low threshold voltage, and therefore can operate at a high speed.

The buffer circuit block 14 includes transistors M32 (p-channel), M33 (p-channel), M34 (n-channel) and M35 (n-channel), which form a NOR circuit. The transistors M33, M34 and M35 form a signal output circuit 14′. A source electrode of the transistor M32 is connected to the supply voltage Vdd, and a drain electrode of the transistor M32 is connected to a source electrode of the transistor M33. A source electrode of the transistor M34 and a source electrode of transistor M35 are connected to the ground GND, and the transistors M34 and M35 are connected in parallel. Outputs from a drain electrode of the transistor M33, a drain electrode of the transistor M34, and a drain electrode of the transistor M35 are output as a binary signal from the buffer circuit block 14. The signal from the transistor M33 is “H” (=Vdd), and the signals from the transistors M34 and M35 are “L” (=GND).

A gate electrode of the transistor M33 and a gate electrode of the transistor M34, both acting as a first input of the buffer circuit block 14, each receive the signal from the network logic circuit block 13. A gate electrode of the transistor M34 and a gate electrode of the transistor M32, both acting as a second input of the buffer circuit block 14, each receive a standby/operation control signal (hereinafter, referred to as a “signal SL”).

In the buffer circuit block 14, the transistor M32 connected to the supply voltage Vdd has a high threshold voltage, and the transistors M33, M34 and M35 each have a low threshold voltage.

While the network logic circuit block 13 is in an operating state, the signal SL is “L”. The transistor M32 having a high threshold voltage, which receives the “L” signal SL, is controlled to be ON, thereby equalizing the potential of the source electrode of the transistor M32 with the level of the supply voltage Vdd. The transistor M35, which also receives the “L” signal SL, is controlled to be OFF. Owing to such a level control of the transistors M32 (ON) and M35 (OFF), the buffer circuit block 14 acts as an inverter circuit for inverting and amplifying a signal from the network logic circuit block 13. Since the signal from the network logic circuit block 13 is received by the transistors M33 and M34 both having a low threshold voltage, the buffer circuit block 14 operates at a high speed.

While the network logic circuit block 13 is in a standby state, the signal SL is “H”. The transistor M32 having a high threshold voltage, which receives the “H“signal SL, is controlled to be OFF, and the transistor M35, which also receives the “H” signal SL, is controlled to be ON. Owing to such a level control of the transistors M32 (OFF) and M35 (ON), the buffer circuit block 14 outputs a fixed “L signal (=0) irrespective of the level of the signal from the network logic circuit block 13. Since the transistor M32, controlled to be OFF, blocks the transistor M33 from the supply voltage Vdd and has a small amount of off-leak current because of its high threshold voltage, the magnitude of the leak current in the buffer circuit block 14 is reduced.

The transistors M33, M34 and M35 are set to have a threshold voltage which is sufficiently low to operate at a high speed with the specific supply voltage used. For example, when the supply voltage Vdd=0.5 V, the threshold voltage of each of the transistors M33, M34 and M35 is set to 0.15 V. The transistor M32 is set to have a threshold voltage which is sufficiently high to reduce the magnitude of the leak current, for example, 0.4 V in this case.

A path logic circuit is a circuit which uses transistors as switching devices and combines gates of the transistors receiving an input signal to form a network, thus performing a logic operation. A path logic circuit includes a network logic circuit for performing a logic operation and a buffer circuit for shaping the waveform of, and amplifying, the signal output from the network logic circuit. An input to a network logic circuit forming such a path logic circuit is fundamentally driven by a buffer circuit of another network logic circuit.

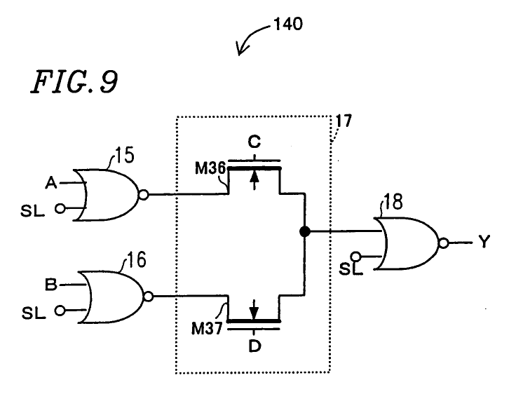

FIG. 9 is a block diagram schematically illustrating such a path logic circuit 140.

The path logic circuit 140 shown in FIG. 9 includes a network logic circuit 17, which includes transistors M36 and M37 both having a low threshold voltage. A source electrode of the transistor M36 is connected a buffer circuit 15, and the transistor M36 is driven by the buffer circuit 15. A source electrode of the transistor M37 is connected a buffer circuit 16, and the transistor M37 is driven by the buffer circuit 16. A drain electrode of the transistor M36 and a drain electrode of the transistor M37 are both connected to an input terminal of a buffer circuit 18. Outputs from the drains of the transistors M36 and M37 are sent to the buffer circuit 18 as outputs from the network logic circuit 17.

The buffer circuits 15, 16 and 18 each include a NOR circuit having two input terminals. One input terminal of the buffer circuit 15 receives signal A, and one input terminal of the buffer circuit 16 receives signal B. One input terminal of the buffer circuit 18 receives a signal from the network logic circuit 17. The other input terminals of the buffer circuits 15, 16 and 18 each receive a signal SL. An output terminal of the buffer circuit 18 outputs signal Y.

Hereinafter, reduction in the magnitude of the leak current realized by the semiconductor integrated circuit 130 of the second example will be described in more detail, with the path logic circuit 140 as an example.

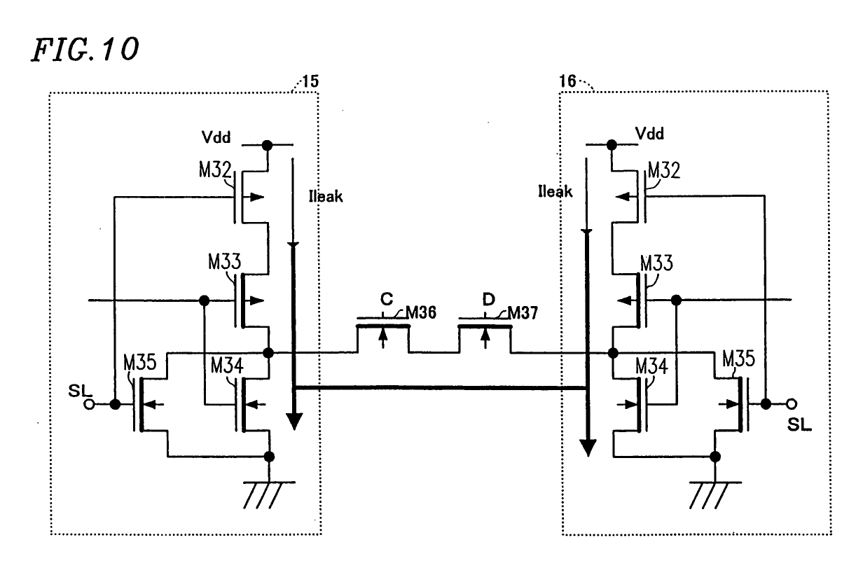

FIG. 10 is a circuit diagram illustrating a leak current path of the path logic circuit 140 (FIG. 9). With reference to FIG. 10, the leak current path when the path logic circuit 140 is in a standby state will be described in more detail. The buffer circuits 15 and 16 each have the same circuit configuration as that of the buffer circuit block 14 shown in FIG. 8.

In the example of FIG. 10, a leak current path is formed in a standby state between the supply voltage Vdd and the ground GND. The leak current path includes the transistors M36 and M37 included in a network logic circuit, and the transistors M32, M33, M34 and M35 in each of the buffer circuits 15 and 16. A leak current Iₗₑₐₖ flowing through the leak current path from the supply voltage Vdd is generated. While the path logic circuit 140 is in a standby state, the signal SL is “H”, and the transistor M32 having a high threshold voltage, which receives the “H” signal SL, is controlled to be OFF. Therefore, the leak current path is isolated from the supply voltage Vdd by the transistor M32, and as a result, the magnitude of the leak current Iₗₑₐₖ flowing through the leak current path can be reduced.

FIG. 11 is a block diagram of a path logic circuit 150 in which one input terminal of the network logic circuit is connected to the supply voltage Vdd in a fixed manner. FIG. 11 is a circuit diagram illustrating a leak current path of the path logic circuit 140 (FIG. 9). With reference to FIG. 11, the leak current path when the path logic circuit 150 is in a standby state will be described in more detail. The buffer circuit 11 has the same circuit configuration as that of the buffer circuit block 14 shown in FIG. 8.

In the example of FIG. 11, while the path logic circuit 150 is in a standby state, the signal SL is “H”, and the transistor M32 having a high threshold voltage, which receives the “H” signal SL, is controlled to be OFF. Therefore, the leak current path is isolated from the supply voltage Vdd by the transistor M32, and as a result, the magnitude of the leak current Iₗₑₐₖ flowing through the leak current path which is from the supply voltage Vdd to the ground GND via the transistor M32 can be reduced.

However, one of the two transistors M37 in the network logic circuit is connected to the supply voltage Vdd. Therefore, while the path logic circuit 150 is in a standby state (non-operating state), a leak current Iₗₑₐₖ is generated flowing from the transistors M37 and M36 in the network logic circuit to the ground GND via the transistor M35 controlled to be ON in the network logic circuit. In order to block the leak path by the buffer circuit 11 stably and certainly so as to reduce the magnitude of the leak current I_{leak,} all the input terminals of the network logic circuit need to be connected to a NOR circuit as shown in FIG. 8 including a transistor which has a high threshold voltage and is connected to the supply voltage Vdd.

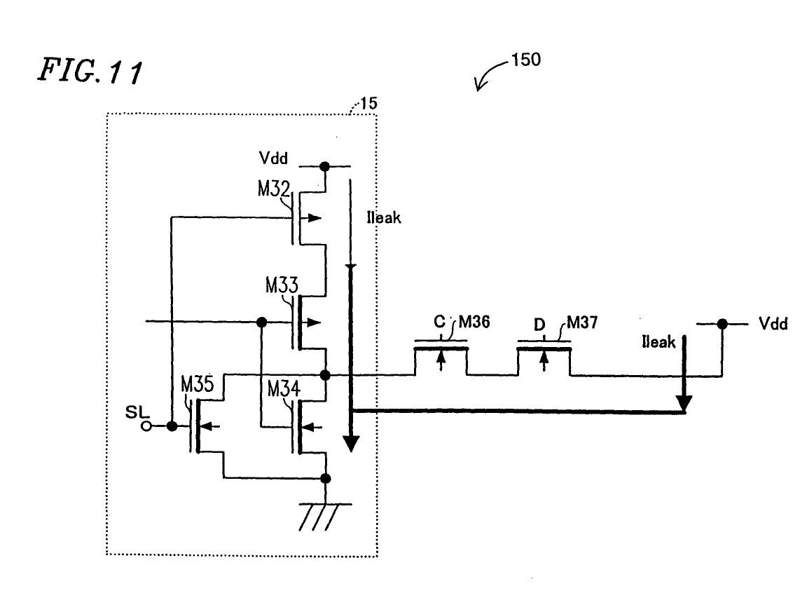

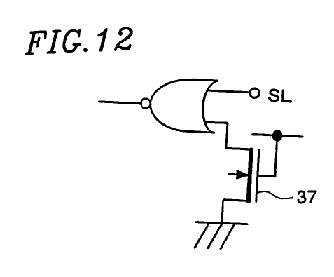

FIG. 12 shows a circuit configuration proposed to eliminate the leak path described above with reference to FIGS. 10 and 11. The circuit configuration shown in FIG. 12 level-clips the source electrode of the transistor M37 to the supply voltage Vdd via a buffer circuit. In this case also, the buffer circuit needs to be a NOR circuit as shown in FIG. 8.

As described above, the semiconductor integrated circuit 130 according to the second example includes a NOR-type buffer circuit block 14. One of the two input terminals of the NOR-type buffer circuit block 14 receives a standby/operation control signal SL, and the signal SL is input to the transistor M32 having a source electrode connected to the supply voltage Vdd. The transistor M32 has a high threshold voltage. The buffer circuit block 14, owing to the above-described structure, can easily reduce the magnitude of the leak current irrespective of the structure of the network logic circuit block 13. While the network logic circuit block 13 is in a standby state, the transistor having a high threshold voltage is controlled to be ON by the signal SL whereas the transistors switched by the input signal have a low threshold voltage. Therefore, the semiconductor integrated circuit 130 can realize high speed processing.

### EXAMPLE 3

FIG. 13 is a block diagram illustrating a semiconductor integrated circuit 160 according to a third example of the present invention. In this example, the semiconductor integrated circuit 160 performs a Y=A·B·C operation, for example.

The semiconductor integrated circuit 160 includes a network logic circuit block 19 for performing a prescribed logic operation so as to generate an operation circuit signal, and a buffer circuit block 20 connected to the network logic circuit block 19 for amplifying the operation circuit signal generated by the network logic circuit block 19.

The network logic circuit block 19 includes therein a first input terminal 7 for receiving signal C, and a second input terminal 8 for receiving signal /C, which is the inverse of signal C. The first input terminal 7 is connected to a source electrode of an n-channel transistor M46 and a source electrode of an n-channel transistor M48. The second input terminal 8 is connected to a source electrode of an n-channel transistor M49. A drain electrode of the transistor M48 and a drain electrode of the transistor M49 are connected to a source electrode of an n-channel transistor M47. Outputs from a drain electrode of the transistor M46 and a drain electrode of the transistor M47 are sent to the buffer circuit block 20 as a binary signal from the network logic circuit block 19.

A gate of the transistor M47 receives signal A, and a gate electrode of the transistor M46 receives signal /A, which is the inverse of signal A. A gate electrode of the transistor M49 receives signal B, and a gate electrode of the transistor M48 receives signal /B, which is the inverse of signal B.

The transistors M46, M47, M48 and M49 included in the network logic circuit block 19 each have a low threshold voltage, and therefore can operate at a high speed.

The buffer circuit block 20 includes transistors M50 (p-channel), M51 (p-channel), M52 (n-channel) and M53 (n-channel), which form a NAND circuit. The transistors M50, M51 and M52 form a signal output circuit 20′. A source electrode of the transistor M50 and a source electrode of the transistor M51 are connected to the supply voltage Vdd, and the transistors M50 and M51 are connected in parallel. A source electrode of the transistor M53 is connected to the ground GND, and a drain electrode of the transistor M53 is connected to a source electrode of the transistor M52. Outputs from a drain electrode of the transistor M50, a drain electrode of the transistor M51, and a drain electrode of the transistor M52 are output as a binary signal from the buffer circuit block 20. The signals from the transistors M50 and M51 are “H” (=Vdd), and the signal from the transistor M52 is “L” (=GND).

A gate electrode of the transistor M50 and a gate electrode of the transistor M52, both acting as a first input of the buffer circuit block 20, each receive the signal from the network logic circuit block 19. A gate electrode of the transistor M51 and a gate electrode of the transistor M53, both acting as a second input of the buffer circuit block 20, each receive a standby/operation control signal (hereinafter, referred to as a “signal SLB”).

In the buffer circuit block 20, the transistor M53 connected to the ground GND has a body electrode. The body electrode is connected to a body potential control terminal VNB. The transistors M50, M51 and M52 each have a low threshold voltage.

While the network logic circuit block 19 is in an operating state, the signal SLB is “H”. In this state, the body potential control terminal VNB connected to the body electrode of the transistor M53 is connected to, for example, the ground GND, and thus the transistor M53 acts as a transistor having a low threshold voltage. The transistor M53, which receives the “H” signal SLB, is controlled to be ON, thereby equalizing the potential of the source electrode of the transistor M52 with the level of the ground GND. The transistor M51, which also receives the “H” signal SLB, is controlled to be OFF. Owing to such a level control of the transistors M51 (OFF) and M53 (ON), the buffer circuit block 20 acts as an inverter circuit for inverting and amplifying a signal from the network logic circuit block 19. Since the signal from the network logic circuit block 19 is received by the transistors M50 and M52 both having a low threshold voltage, the buffer circuit block 20 operates at a high speed.

While the network logic circuit block 19 is in a standby state (non-operating state), the signal SLB is “L”. In this state, the body potential control terminal VNB connected to the body electrode of the transistor M53 is supplied with a potential GND-α. This makes the threshold voltage of the transistor M53 high, so that the transistor M53 acts as a transistor having a high threshold voltage. The transistor M53 having a high threshold voltage, which receives the “L” signal SLB, is controlled to be OFF, and the transistor M51, which also receives the “L” signal SLB, is controlled to be ON. Owing to such a level control of the transistors M51 (ON) and M53 (OFF), the buffer circuit block 20 outputs a fixed “H” signal (=Vdd) irrespective of the level of the signal from the network logic circuit block 19. Since the transistor M53, supplied with a potential GND-a at the body electrode and thus controlled to be OFF, blocks the transistor M52 from the ground GND and has a small amount of off-leak current because of its high threshold voltage, the magnitude of the leak current in the buffer circuit block 20 is reduced.

The buffer circuit block 20 according to the third example includes a NAND circuit as described above. A buffer circuit block having a NOR circuit as described in the second example may use a transistor having a body electrode. In such a case, a transistor having a source electrode connected to the supply voltage Vdd has a body electrode, and the body electrode is supplied with a potential Vdd while the network logic circuit block 19 is in an operating state. In this manner, the threshold voltage of this transistor is lowered. While the network logic circuit block 19 is in a standby state, the body electrode is supplied with a higher potential (Vdd+α) to make the threshold voltage of this transistor, so as to reduce the magnitude of the leak current.

Regardless of whether the buffer circuit block 20 includes a NAND circuit or a NOR circuit, all the transistors included in the buffer circuit block 20 may each have a body electrode. In such a case, the threshold voltages of the transistors are raised while the network logic circuit block 19 is in a standby state, and lowered while the network logic circuit block 19 is in an operating state. In this way, a high speed operation and reduction in the magnitude of the leak current can both be realized, although the area of the buffer circuit block 20 is increased.

### EXAMPLE 4

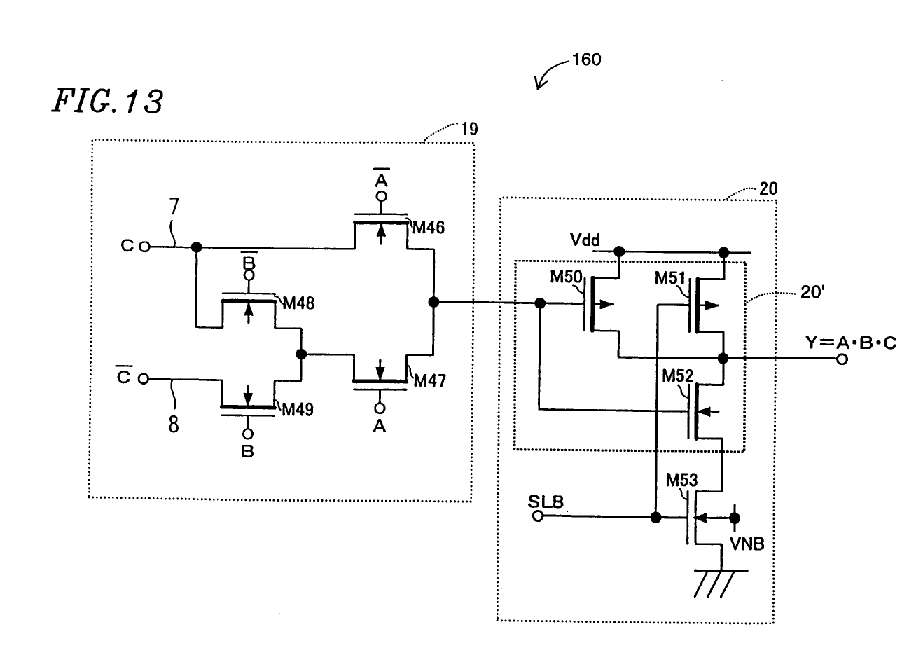

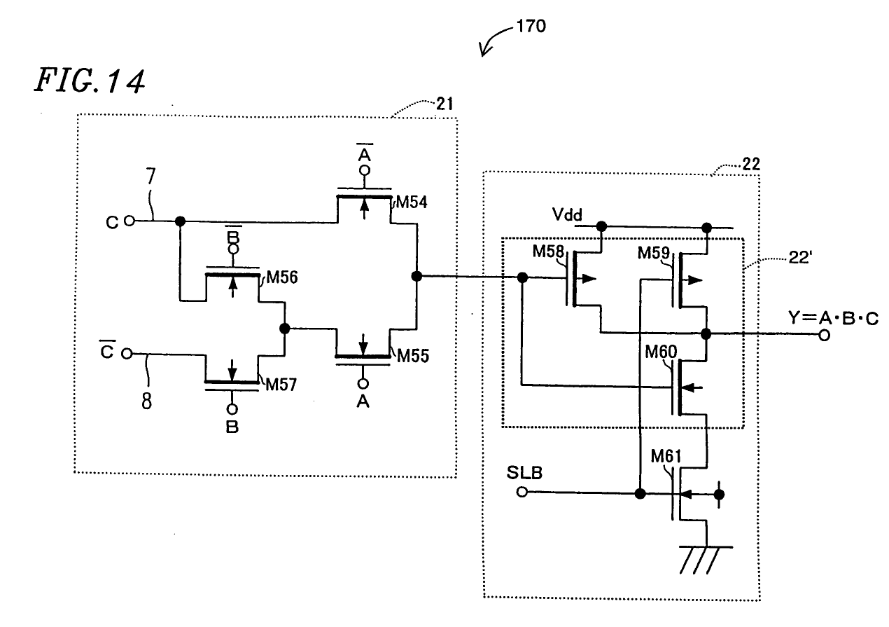

FIG. 14 is a block diagram illustrating a semiconductor integrated circuit 170 according to a fourth example of the present invention. In this example, the semiconductor integrated circuit 170 performs a Y=A·B·C operation, for example.

The semiconductor integrated circuit 170 includes a network logic circuit block 21 for performing a prescribed logic operation so as to generate an operation circuit signal, and a buffer circuit block 22 connected to the network logic circuit block 21 for amplifying the operation circuit signal generated by the network logic circuit block 21.

The network logic circuit block 21 includes therein a first input terminal 7 for receiving signal C, and a second input terminal 8 for receiving signal /C, which is the inverse of signal C. The first input terminal 7 is connected to a source electrode of an n-channel transistor M54 and a source electrode of an n-channel transistor M56. The second input terminal 8 is connected to a source electrode of an n-channel transistor M57. A drain electrode of the transistor M56 and a drain electrode of the transistor M57 are connected to a source electrode of an n-channel transistor M55. Outputs from a drain electrode of the transistor M54 and a drain electrode of the transistor M55 are sent to the buffer circuit block 22 as a binary signal from the network logic circuit block 21.

A gate of the transistor M55 receives signal A, and a gate electrode of the transistor M54 receives signal /A, which is the inverse of signal A. A gate electrode of the transistor M57 receives signal B, and a gate electrode of the transistor M56 receives signal /B, which is the inverse of signal B.

The transistors M54, M55, M56 and M57 included in the network logic circuit block 21 each have a low threshold voltage, and therefore can operate at a high speed.

The buffer circuit block 22 includes transistors M58 (p-channel), M59 (p-channel), M60 (n-channel) and M61 (n-channel), which form a NAND circuit. The transistors M58, M59 and M60 form a signal output circuit 22′. A source electrode of the transistor M58 and a source electrode of the transistor M59 are connected to the ground GND, and the transistors M58 and M59 are connected in parallel. A source electrode of the transistor M61 is connected to the ground GND, and a drain electrode of the transistor M61 is connected to a source electrode of the transistor M60. Outputs from a drain electrode of the transistor M58, a drain electrode of the transistor M59, and a drain electrode of the transistor M60 are output as a binary signal from the buffer circuit block 22. The signals from the transistors M58 and M59 are “H” (=Vdd), and the signal from the transistor M60 is “L” (=GND).

A gate electrode of the transistor M58 and a gate electrode of the transistor M60, both acting as a first input of the buffer circuit block 22, each receive the signal from the network logic circuit block 21. A gate electrode of the transistor M59 and a gate electrode of the transistor M61, both acting as a second input of the buffer circuit block 22, each receive a standby/operation control signal (hereinafter, referred to as a “signal SLB”).

In the buffer circuit block 22, the transistor M61 connected to the ground GND has a body electrode. The body electrode is connected to the gate electrode of the transistor M61. The transistors M58, M59 and M60 each have a low threshold voltage.

In the case where body electrode and the gate electrode of the same transistor are connected to each other as in the transistor M61, the gate electrode is supplied with a voltage so as to form a channel and the voltage between the body region and the source region is biased forward. As a result, the threshold voltage of the transistor is reduced.

While the network logic circuit block 21 is in an operating state, the signal SLB is “H”. The transistor M61, which receives the “H” signal SLB, is controlled to be ON, thereby equalizing the potential of the source electrode of the transistor M60 with the level of the ground GND. Since the “H” signal SLB is supplied to the body electrode of the transistor M61, the threshold voltage of the transistor M61 is lowered, and the magnitude of the saturation current of the transistor 61 is increased. The transistor M59, which also receives the “H” signal SLB, is controlled to be OFF. Owing to such a level control of the transistors M59 (OFF) and M61 (ON), the buffer circuit block 22 acts as an inverter circuit for inverting and amplifying a signal from the network logic circuit block 21. The signal from the network logic circuit block 21 is received by the transistors M58 and M60 both having a low threshold voltage. The threshold voltage of the transistor M61 is also lower than its threshold voltage in a standby state. Since all the transistors involved in input/output of signals while the network logic circuit block 21 are low, the buffer circuit block 22 operates at a high speed.

While the network logic circuit block 21 is in a standby state (non-operating state), the signal SLB is “L”. The transistor M61, which receives the “L” signal SLB, is controlled to be OFF, and the transistor M59, which also receives the “L” signal SLB, is controlled to be ON. The threshold voltage of the transistor M61, in which the body electrode is connected to the gate electrode, is kept high owing to the “L” signal SLB. Owing to such a level control of the transistors M59 (ON) and M61 (OFF), the buffer circuit block 22 outputs a fixed “H” signal (=Vdd) irrespective of the level of the signal from the network logic circuit block 21. Since the transistor M61, controlled to be OFF and having a high threshold voltage, isolates the source electrode of the transistor M60 from the ground GND and has a small amount of off-leak current because of its high threshold voltage, the magnitude of the leak current in the buffer circuit block 22 is reduced.

The buffer circuit block 22 according to the fourth example includes a NAND circuit as described above. A buffer circuit block having a NOR circuit as described in the second example may use a transistor having a body electrode. In such a case, a transistor having a source electrode connected to the supply voltage Vdd has a body electrode, and the body electrode is connected to the gate electrode of the same transistor. Thus, the threshold voltage of the transistor is low while the network logic circuit block 21 is in an operating state, and high while the network logic circuit block 21 is in a standby state. Owing to the threshold voltage being high while the network logic circuit block 21 is in a standby state, the magnitude of the leak current in the standby state can be reduced.

Regardless of whether the buffer circuit block 22 includes a NAND circuit or a NOR circuit, all the transistors included in the buffer circuit block 22 may each have a body electrode, which is connected to the gate electrode of the same transistor. In such a case, the threshold voltages of the transistors are raised while the network logic circuit block 21 is in a standby state, and lowered while the network logic circuit block 21 is in an operating state. In this way, a high speed operation and reduction in the magnitude of the leak current can both be realized, although the area of the buffer circuit block 22 is increased.

The above-described transistor having a body electrode connected to the gate electrode, which is included in the buffer circuit block 22, has a problem in that the magnitude of the leak current increases due to a forward diode formed between the source electrode and the body electrode especially when the supply voltage used is high. This problem is not serious when the supply voltage used is low (for example, Vdd≧0.8 V).

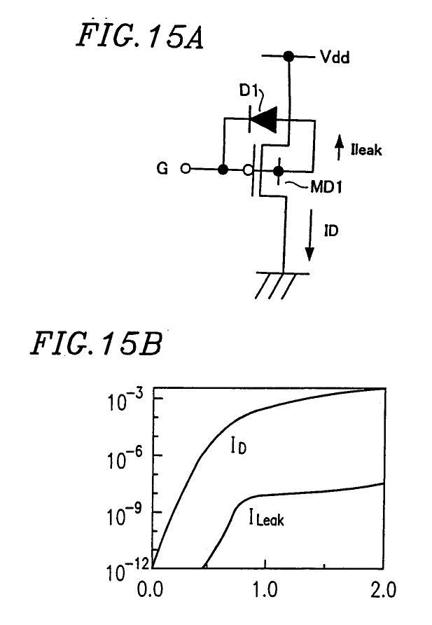

FIG. 15A shows an exemplary configuration of a transistor MD1 for solving this problem of increasing leak current. In the transistor MD1, a diode D1 is inserted between the body electrode and the gate electrode such that the voltage is biased reversely when the current flows from the body electrode to the gate electrode. This configuration suppresses the magnitude of the leak current from the body electrode to the gate electrode. FIG. 15B is a graph illustrating the relationship between the supply voltage and the drain current ID and the leak current Iₗₑₐₖ. The horizontal axis represents the current value, and the vertical axis represents the supply voltage. As can be clear from this graph, the leak current Iₗₑₐₖ in the region where the supply voltage is high (0.8 V or higher) is suppressed by the diode D1 inserted between the body electrode and the gate electrode.

In the buffer circuit block 22 shown in FIG. 14, the leak current can be reduced by replacing the transistor M61 with the transistor MD1 shown in FIG. 15A.

Hereinafter, a transistor using SOI (Silicon on Insulator) technology, which can be effectively used in the first through fourth examples will be described.

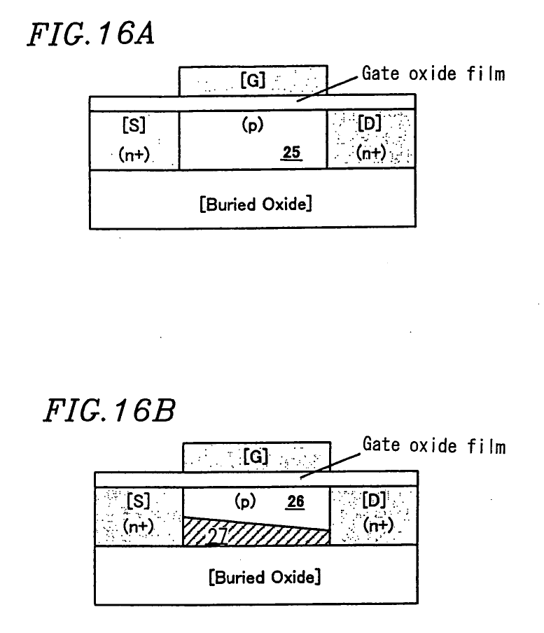

FIGS. 16A and 16B are each a cross-sectional view of a transistor having an SOI structure. FIG. 16A shows a fully depleted (FD) transistor, and FIG. 16B shows a partially depleted (PD) transistor.

In the FD transistor shown in FIG. 16A, a channel region formed on a buried oxide film is fully depleted. On the buried oxide film, an n-channel source electrode and an n-channel drain electrode are formed so as to surround the channel region. A gate electrode is formed on the channel region with a gate oxide film interposed therebetween. Due to the fully depleted channel region, this transistor has a steep sub-threshold characteristic, and thus allows a lower threshold voltage to be set. Therefore, this transistor can be operated at a high speed and at a low voltage.

In the PD transistor shown in FIG. 16B, a channel region formed on a buried oxide film includes a depleted region 26 and a non-depleted region 27. An n-channel source electrode and an n-channel drain electrode are formed on the buried oxide film so as to surround the channel region. A gate electrode is formed on the channel region with a gate oxide film interposed therebetween. In the case where the non-depleted region 27 of this transistor is supplied with a body bias, various types of transistors described in the third and fourth examples with the body potential being controlled can be realized.

As shown in FIGS. 16A and 16B, the SOI-structure transistor includes a source region and a drain region which are both surrounded by an oxide film, and therefore has a small junction capacitance. This reduces power consumption. As described above with reference to FIG. 16A, owing to a steep sub-threshold characteristic, the SOI-structure transistor can obtain a larger magnitude of current than a bulk MOS device or the like even when the voltage between the source region and the drain electrode is small. This is suitable for a path logic circuit. With an SOI structure, even when the path gate is formed of a CMOS transistor, the increase in the area and the load capacitance caused by the CMOS structure can be suppressed as compared with the case of a bulk MOS device or the like. This is very suitable for a path logic circuit according to the present invention.

### EXAMPLE 5

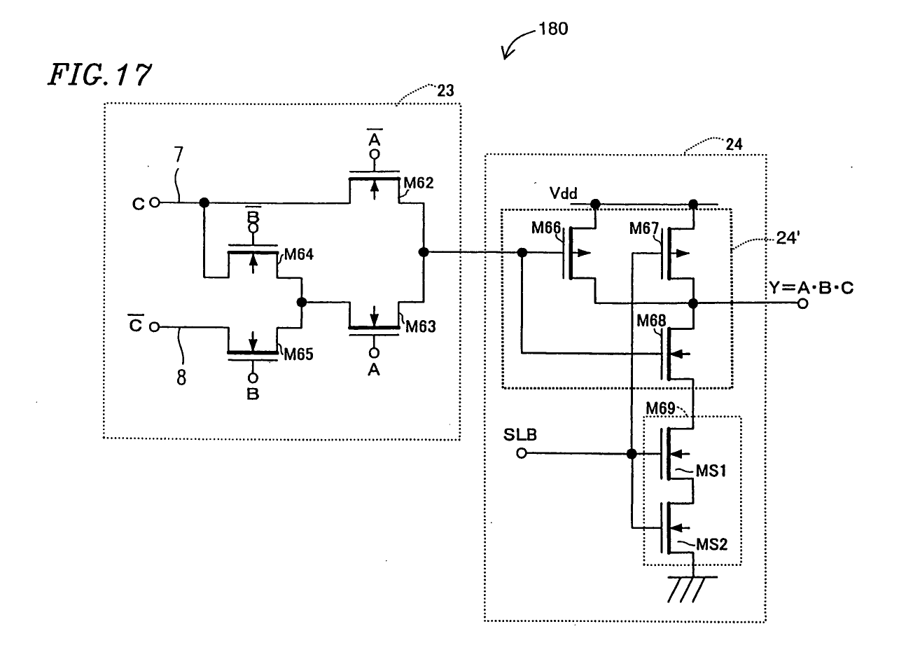

FIG. 17 is a block diagram illustrating a semiconductor integrated circuit 180 according to a fifth example of the present invention. In this example, the semiconductor integrated circuit 180 performs a Y=A·B·C operation, for example.

The semiconductor integrated circuit 180 includes a network logic circuit block 23 for performing a prescribed logic operation so as to generate an operation circuit signal, and a buffer circuit block 24 connected to the network logic circuit block 23 for amplifying the operation circuit signal generated by the network logic circuit block 23.

The network logic circuit block 23 includes therein a first input terminal 7 for receiving signal C, and a second input terminal 8 for receiving signal /C, which is the inverse of signal C. The first input terminal 7 is connected to a source electrode of an n-channel transistor M62 and a source electrode of an n-channel transistor M64. The second input terminal 8 is connected to a source electrode of an n-channel transistor M65. A drain electrode of the transistor M64 and a drain electrode of the transistor M65 are connected to a source electrode of an n-channel transistor M63. Outputs from a drain electrode of the transistor M62 and a drain electrode of the transistor M63 are sent to the buffer circuit block 24 as a binary signal from the network logic circuit block 23.

A gate of the transistor M63 receives signal A, and a gate electrode of the transistor M62 receives signal /A, which is the inverse of signal A. A gate electrode of the transistor M65 receives signal B, and a gate electrode of the transistor M64 receives signal /B, which is the inverse of signal B.

The transistors M62, M63, M64 and M65 included in the network logic circuit block 23 each have a low threshold voltage, and therefore can operate at a high speed.

The buffer circuit block 24 includes transistors M66 (p-channel), M67 (p-channel), M68 (n-channel) and M69 (n-channel), which form a NAND circuit. The transistors M66, M67 and M68 form a signal output circuit 24′. A source electrode of the transistor M66 and a source electrode of the transistor M67 are connected to the supply voltage Vdd, and the transistors M66 and M67 are connected in parallel. The transistor M69 includes two n-channel transistors MS1 and MS2 connected in series. A source electrode of the transistor M69 (i.e., a source electrode of the transistor MS2) is connected to the ground GND, and a drain electrode of the transistor M69 (i.e., a drain electrode of the transistor MS1) is connected to a source electrode of the transistor M68. Outputs from a drain electrode of the transistor M66, a drain electrode of the transistor M67, and a drain electrode of the transistor M68 are output as a binary signal from the buffer circuit block 24. The signals from the transistors M66 and M67 are “H” (=Vdd), and the signal from the transistor M68 is “L” (=GND).

A gate electrode of the transistor M66 and a gate electrode of the transistor M68, both acting as a first input of the buffer circuit block 24, each receive the signal from the network logic circuit block 23. A gate electrode of the transistor M67 and a gate electrode of each of the transistors MS1 and MS2, all acting as a second input of the buffer circuit block 24, each receive a standby/operation control signal (hereinafter, referred to as a “signal SLB”).

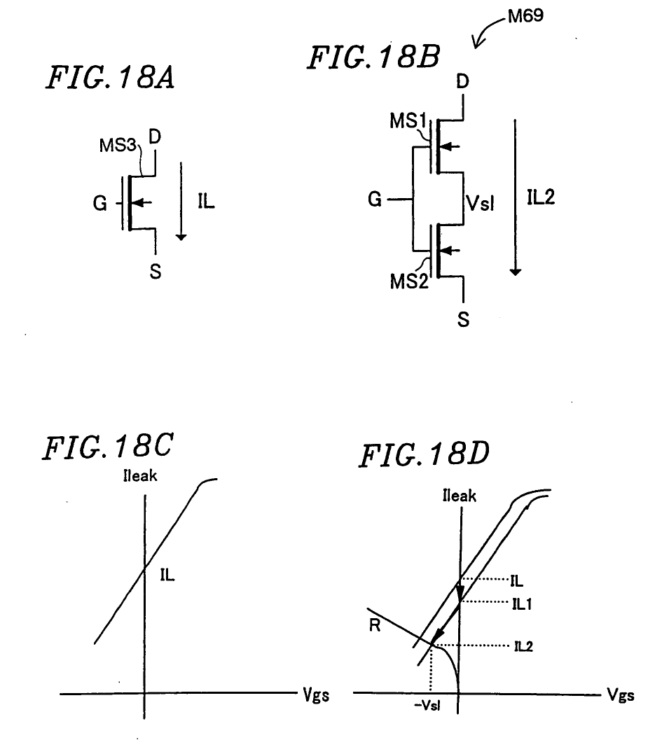

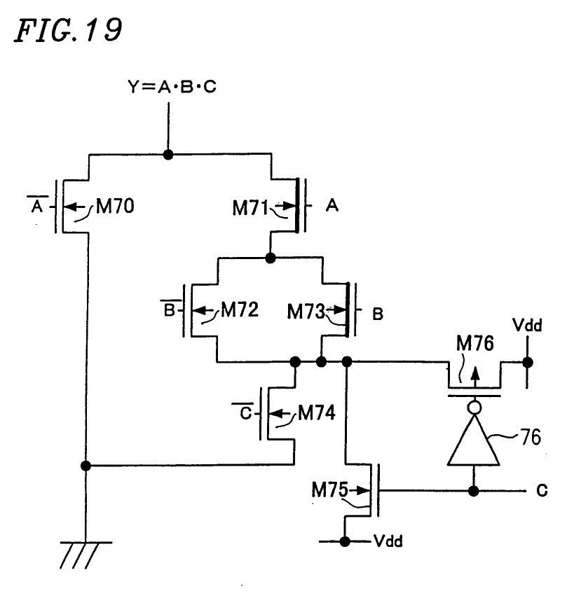

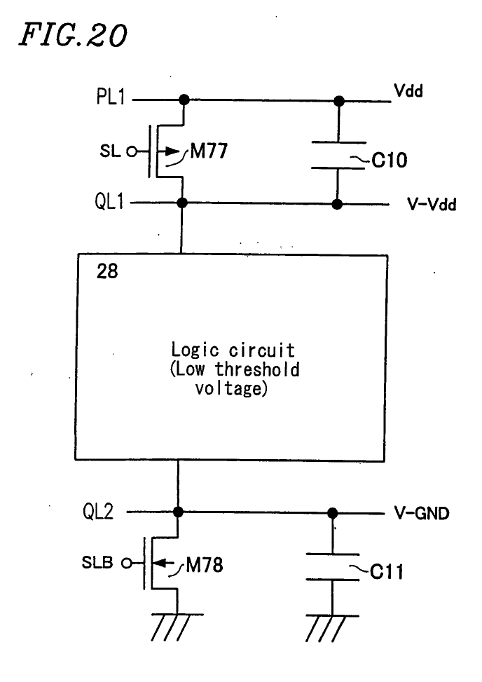

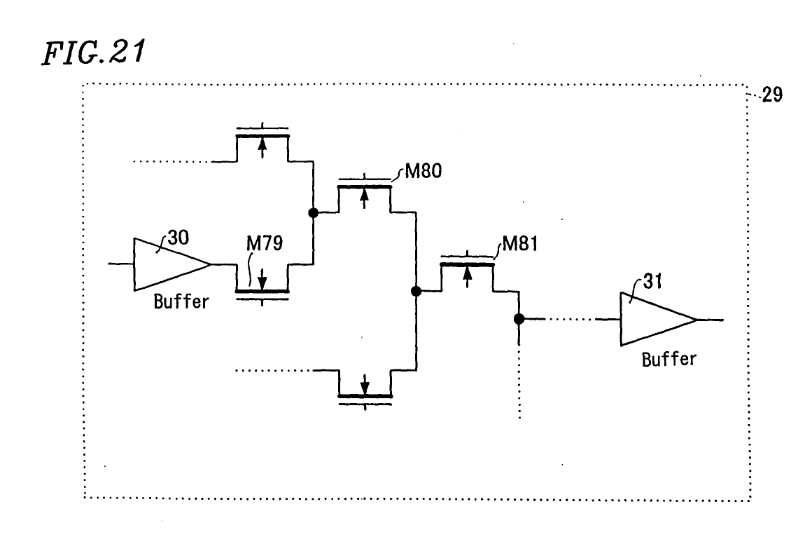

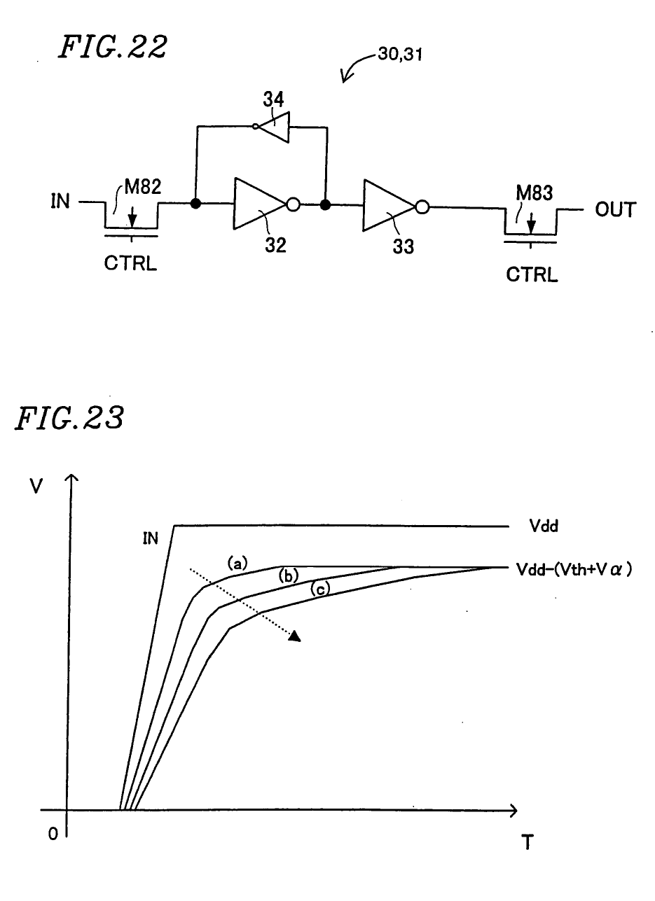

An operation of the transistor M69 will be described with reference to FIGS. 18A through 18D. FIG. 18A shows a circuit configuration of a single transistor MS3 having a low threshold voltage, for comparison. FIG. 18B shows a circuit configuration of the transistor M69 including the transistors MS1 and MS2 connected in series. The transistors MS1 and MS2 each have a low threshold voltage. The transistors M66, M67, M68, MS1 and MS2 may have threshold voltages having an equal absolute value. A gate electrode of the transistor MS1 and a gate electrode of the transistor MS2 are connected to each other and thus act as a common gate electrode.

The transistor MS3 (FIG. 18A) has a disadvantage that the magnitude of the leak current is increased when the network logic circuit block is in a standby state. In contrast, the transistor M69 can reduce the magnitude of the leak current owing to the serial connection of the two transistors MS1 and MS2.

The reason why the transistor M69 can reduce the magnitude of the leak current will be described with reference to FIGS. 18C and 18D. FIG. 18C is a graph illustrating an off-leak current characteristic of the transistor MS3. FIG. 18D is a graph illustrating an off-leak current characteristic of the transistor M69. In FIGS. 18C and 18D, the horizontal axis represents the voltage Vgs between the gate electrode and the source electrode, and the vertical axis represents the magnitude of the off-leak current Iₗₑₐₖ.

When the single transistor MS3 is used, the magnitude of the off-leak current Iₗₑₐₖ is high in a standby state (Vgs=0) as shown in FIG. 18C since the threshold voltage of the transistor MS3 is set to be low. The level of the off-leak current Iₗₑₐₖ when Vgs=0 in FIG. 18C is represented as “IL”.

The transistors MS1 and MS2 connected in series so as to form the transistor M69 each have a low threshold voltage like the transistor MS3. However, owing to the serial connection, each of the transistors MS1 and MS2 is supplied with a divided voltage. As a result, the source potential of the transistor MS1 is Vs1 (FIG. 18D), which is higher than the source potential of the transistor MS3 Therefore, because of the substrate bias effect, the off-leak current curve of the transistor M69 is translated in a negative direction with respect to the vertical axis, as compared to that of the transistor MS3 (FIG. 18C). Thus, the magnitude of the off-leak current Iₗₑₐₖ in a standby state (Vgs=0) is IL1 (FIG. 18D), which is lower than IL shown in FIG. 18C.

In addition, the transistor MS2 connected in series to the transistor MS1 acts as a load. The transistor MS2 has a load characteristic R shown in FIG. 18D. Because of the load, the gate potential of the transistor MS1 is 0 and the source potential of the transistor MS1 is Vs1 in a standby state. As a result, the voltage Vgs of the transistor MS1 is −Vs1. The magnitude of the leak current Iₗₑₐₖ of the transistor MS1 is obtained from an intersection of the load curve of the transistor MS2 and the off-leak curve of the transistor MS1. Therefore, the magnitude of the leak current Iₗₑₐₖ of the transistor MS1 is IL2, which is still lower than IL1. For the above-described reason, the magnitude of the leak current Iₗₑₐₖ can be significantly reduced when two transistors MS1 and MS2 connected in series are used as compared to when the single transistor MS3 is used.

In the case where two transistors connected in series, in which the gate electrodes thereof are connected to each other, are used, the magnitude of the leak current can be reduced even when the buffer circuit includes only transistors having a low threshold voltage. It is not necessary to use a special step for providing transistors having different threshold voltages for specified locations. Therefore, a circuit realizing a high speed operation and reduction in the magnitude of the leak current can be provided at low cost.

Returning to FIG. 17, while the network logic circuit block 23 is in an operating state, the signal SLB is “H”. The transistor M69, which receives the “H” signal SLB, is controlled to be ON (i.e., the transistors MS1 and MS2 are controlled to be ON), thereby equalizing the potential of the source electrode of the transistor M68 with the level of the ground GND. The transistor M67, which also receives the “H” signal SLB, is controlled to be OFF. Owing to such a level control of the transistors M67 (OFF) and M69 (ON), the buffer circuit block 24 acts as an inverter circuit for inverting and amplifying a signal from the network logic circuit block 23. Since the signal from the network logic circuit block 23 is received by the transistors M66 and M68 both having a low threshold voltage, the buffer circuit block 24 operates at a high speed.

While the network logic circuit block 23 is in a standby state (non-operating state), the signal SLB is “L”. The transistor M69, which receives the “L” signal SLB, is controlled to be OFF (i.e., the transistors MS1 and MS2 are controlled to be OFF), and the transistor M67, which also receives the “L” signal SLB, is controlled to be ON. Owing to such a level control of the transistors M67 (ON) and M69 (OFF), the buffer circuit block 24 outputs a fixed “H” signal (=Vdd) irrespective of the level of the signal from the network logic circuit block 23. Since the transistor M69, controlled to be OFF, includes the two transistors MS1 and MS2 connected in series, the gate electrodes thereof being connected to each other, the magnitude of the leak current in the buffer circuit block 24 is reduced.

The buffer circuit block 24 according to the fifth example includes a NAND circuit as described above. A buffer circuit block having a NOR circuit as described in the second example may use a transistor including two transistors connected in series, in which the gate electrodes thereof are connected to each other. In such a case, a transistor having a source electrode connected to the supply voltage Vdd is formed of two transistors connected in series as shown in FIG. 18B (in this case, p-channel transistors). In this case also, the magnitude of the leak current is reduced in a standby state owing to the two transistors connected in series.

In the first through fifth examples, the network logic circuit block includes n-channel transistors. All the transistors included in the network logic circuit block may be p-channel transistors or may include n-channel transistors and p-channel transistors in a mixed manner. In such cases, the same effects are provided. The transistors M14 and M16, for example, shown in FIG. 2 may form a CMOS transistor.

As described above, a semiconductor integrated circuit according to the present invention includes a switching device for turning OFF the supply of a voltage to a signal output circuit when the logic operation circuit is in a non-operating state. Owing to this structure, the magnitude of the leak current in the non-operating state can be reduced.

According to the present invention, since the semiconductor integrated circuit includes the signal output circuit and the switching device, the magnitude of the leak current in a non-operating state can be easily reduced by a simple circuit configuration regardless of the structure of the network logic circuit. Thus, the magnitude of the leak current in a non-operating state can be reduced without troublesome operations of analyzing the leak path and inserting a transistor having a high threshold voltage for each path, without unnecessarily increasing the chip area, or without increasing the number of transistors and thus without deteriorating the characteristics of the network logic circuit.

According to the present invention, the switching device for turning OFF the supply of a voltage to the signal output circuit in a non-operating state may be, for example, a transistor having a high threshold voltage, a transistor having a body electrode having an adjustable threshold voltage, a transistor having a gate electrode and a body electrode connected to each other, or a combination of a plurality of transistors having a low threshold voltage connected in series. Since such a switching device, which can effectively prevent the leak current is used, transistors having a low threshold voltage can be used for other switching devices in the semiconductor integrated circuit. Thus, a semiconductor integrated circuit operating at a high speed while preventing leak current in a non-operating state can be provided.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A semiconductor integrated circuit, comprising:
a signal output circuit including a first switching device and a second switching device; and
a third switching device,
wherein:
the first switching device is supplied with a first voltage via the third switching device,
the second switching device is supplied with a second voltage,
the signal output circuit receives a first binary signal, and outputs at least one of two values of a second binary signal based on the first binary signal, the first voltage and the second voltage, and
the third switching device receives a control signal for controlling the third switching device to be in an ON state or in an OFF state; and when the third switching device is in the OFF state, the third switching device turns OFF the supply of the first voltage to the first switching device.

2. A semiconductor integrated circuit according to claim 1, wherein:
the first switching device, the second switching device, and the third switching device are transistors, and
the third switching device has a threshold voltage which is higher than a threshold voltage of the first switching device and a threshold voltage of the second switching device.

3. A semiconductor integrated circuit according to claim 1, wherein:
the signal output circuit further includes a fourth switching device supplied with the second voltage,
the fourth switching device receives the control signal and is controlled to be in an ON state when the third switching device is in an OFF state, and
when the fourth switching device is in an ON state, the signal output signal outputs one of two values of the second binary signal and does not output the other value irrespective of the value of the first binary signal.

4. A semiconductor integrated circuit according to claim 3, wherein:
the first switching device, the second switching device, the third switching device, and the fourth switching device form a NAND circuit for receiving the first binary signal and the control signal,
the first voltage is a ground voltage, and
the third switching device is an n-channel transistor, and a source electrode of the third switching device is grounded.

5. A semiconductor integrated circuit according to claim 3, wherein:
the first switching device, the second switching device, the third switching device, and the fourth switching device form a NOR circuit for receiving the first binary signal and the control signal,
the first voltage is a supply voltage, and
the third switching device is a p-channel transistor, and a source electrode of the third switching device is supplied with the supply voltage.

6. A semiconductor integrated circuit according to claim 1, further comprising a logic operation circuit for performing a logic operation, wherein the first binary signal represents a result of the logic operation performed by the logic operation circuit.

7. A semiconductor integrated circuit according to claim 1, wherein the first voltage is one of a supply voltage and a ground voltage, and the second voltage is the other of the supply voltage and the ground voltage.

8. A semiconductor integrated circuit according to claim 1, wherein:
the third switching device is a transistor having a body electrode, and
the third switching device has a threshold voltage which changes based on the voltage applied to the body electrode.

9. A semiconductor integrated circuit according to claim 8, wherein:
the first switching device and the second switching device are transistors, and
when the third switching device is in an OFF state, the threshold voltage of the third switching device is higher than a threshold voltage of the first switching device and a threshold voltage of the second switching device.

10. A semiconductor integrated circuit according to claim 1, wherein:
the third switching device is a transistor having a gate electrode and a body electrode, and
the gate electrode and the body electrode are electrically connected to each other.

11. A semiconductor integrated circuit according to claim 10, further comprising a diode connected between the gate electrode and the body electrode.

12. A semiconductor integrated circuit according to claim 1, wherein at least one of the first switching device, the second switching device, and third switching device is a transistor having an SOI structure.

13. A semiconductor integrated circuit according to claim 1, further comprising a fourth switching device connected between the first switching device and the third switching device,
wherein:
the third switching device and the fourth switching device are transistors,
the third switching device and the fourth switching device are connected in series, and
when the third switching device is in an ON state, the fourth switching device is in an ON state; and when the third switching device is in an OFF state, the fourth switching device is in an OFF state.

14. A semiconductor integrated circuit according to claim 13, wherein:
the first switching device, the second switching device, the third switching device, and the fourth switching device are transistors, and
the first switching device, the second switching device, the third switching device, and the fourth switching device have threshold voltages having an equal absolute value.

15. A semiconductor integrated circuit according to claim 1, wherein the first switching device and the second switching device form a complementary switching device.
